(19) United States
(12) Patent Application Publication
(10) Pub. No.: US 2021/0343572 A1
(43) Pub. Date: Nov. 4, 2021

(54) Method for Transferring Massive Light Emitting Diodes and Display Back Plate Assembly

(71) Applicant: CHONGQING KONKA PHOTOELECTRIC TECHNOLOGY RESEARCH INSTITUTE CO., LTD., Chongqing (CN)

(72) Inventors: Chen HUNG-WEN, Chongqing (CN); Biao TANG, Chongqing (CN); Xintong LI, Chongqing (CN)

(21) Appl. No.: 17/377,420

(22) Filed: Jul. 16, 2021

Related U.S. Application Data
(63) Continuation of application No. PCT/CN2020/076446, filed on Feb. 24, 2020.

(51) Int. Cl. H01L 21/683; H01L 25/075; H01L 33/62

(52) U.S. Cl. CPC H01L 21/6835; H01L 25/0753; H01L 33/62; H01L 2933/0066; H01L 2221/68368; H01L 2221/68386; H01L 2221/68354

(57) ABSTRACT

The disclosure provides a method for transferring massive light emitting diodes and a display back plate assembly, the method includes: a plurality of temporary substrates are provided, light emitting diodes with one color are arranged on one of the plurality of temporary substrates, and the light emitting diodes with different colors are different in height; an adhesive layer on each of the plurality of temporary substrates is coating respectively, so that the adhesive layer covers the light emitting diodes and the adhesive layer on each of the plurality of temporary substrates is the same in height; the adhesive layer between adjacent light emitting diodes to form a flattening layer on one side, far away from the temporary substrate, of the light emitting diodes with the different colors is removed; and the light emitting diodes on each of the plurality of temporary substrates are transferred to a same display back plate.

### TECHNICAL FIELD

The disclosure relates to the technical field of micro light emitting diodes (Micro-LEDs), in particular to a method for transferring massive light emitting diodes and a display back plate assembly.

### BACKGROUND

Micro light emitting diodes (Micro-LEDs) which adopt light emitting diode micro-scaling and matrixing technologies, have good stability, lifetime, and operating temperature advantages. The micro light emitting diode also inherits the advantages of low power consumption, high color saturation, high reaction speed, strong contrast and the like of the light emitting diode. Meanwhile, the micro light emitting diode has the advantages of higher brightness, lower power consumption and the like.

Therefore, micro light emitting diodes will have great application prospects in the future, such as micro light emitting diode display screens. At present, however, the biggest bottleneck of manufacturing the micro light emitting diode display screen is how to enable the micro light emitting diode display screens to be mass-produced. The most effective way to realize mass production is to realize mass transfer. According to the existing method for transferring massive light emitting diodes, red, blue and green micro light emitting diodes need to be respectively transferred to the display back plate, namely three times of transfer are carried out, and the transfer process is complicated. In addition, because the manufacturing processes are different, the micro light emitting diodes with the different colors are different in height, and the micro light emitting diodes with different heights cause greater difficulty in the transfer process.

Therefore, it is an urgent problem to overcome the problem how to efficiently transfer micro light emitting diodes of different heights.

### SUMMARY

The disclosure provides a method for transferring massive light emitting diodes, which can transfer red, blue and green micro light emitting diodes with different heights to a display back plate at one time, simplify the transfer process and save the transfer time.

In a first aspect, the embodiments of the disclosure provides a method for transferring massive light emitting diodes, including:

providing a plurality of temporary substrates, wherein light emitting diodes with one color are arranged on one of the plurality of temporary substrates, and the light emitting diodes with different colors are different in height;

respectively coating an adhesive layer on each of the plurality of temporary substrates, so that the adhesive layer covers the light emitting diodes and the adhesive layer on each of the plurality of temporary substrates is the same in height;

removing the adhesive layer between adjacent light emitting diodes to form a flattening layer on one side, far away from the temporary substrate, of the light emitting diodes with the different colors; and

transferring the light emitting diodes on each of the plurality of temporary substrates to a same display back plate.

In a second aspect, the embodiments of the disclosure also provides a method for transferring massive light emitting diodes, including:

attaching light emitting diodes with different colors from corresponding original substrates to a same temporary substrate, wherein the light emitting diodes with the different colors are different in height;

coating an adhesive layer on the temporary substrate, so that the adhesive layer covers the light emitting diodes and the adhesive layer is the same in height;

removing the adhesive layer between adjacent light emitting diodes to form a flattening layer on one side, far away from the temporary substrate, of the light emitting diodes with the different colors; and

transferring the light emitting diodes on the temporary substrate to a display back plate.

In a third aspect, embodiment of the present disclosure provides a display back plate assembly, including:

a display back plate;

light emitting diodes with different colors arranged on the display back plate, wherein the light emitting diodes with the different colors are different in height; and

a flattening layer formed on one side, far away from the display back plate, of the light emitting diodes with the different colors, wherein distances are the same, and the distance is from one side, far away from the display back plate, of a part of the flattening layer corresponding to each light emitting diode to the display back plate.

According to the method for transferring massive light emitting diodes and the display back plate assembly, the adhesive layer is coated on the light emitting diodes with the different colors, so that a flattening layer is formed on one side, far away from the temporary substrate, of the light emitting diodes with the different colors, and the distances are the same, and the distance is from one side, far away from the display back plate, of a part of the flattening layer corresponding to each light emitting diode to the display back plate. The light emitting diodes are transferred to the display back plate through the transfer device, so that the light emitting diodes with different heights and the different colors can be transferred to the display back plate at one time.

### BRIEF DESCRIPTION OF THE DRAWINGS

FIG. 1 is a flow chart of a method for transferring massive light emitting diodes provided in a first embodiment of the present disclosure.

FIG. 2 is a flow chart of a method for transferring massive light emitting diodes provided in a second embodiment of the present disclosure.

FIG. 3 is a schematic diagram of a process of transferring massive light emitting diodes provided in a first specific embodiment of the first embodiment of the present disclosure.

FIG. 4 is a schematic diagram of a process of transferring massive light emitting diodes provided in a second specific embodiment of the first embodiment of the present disclosure.

FIG. 5 is a schematic diagram of a process of transferring massive light emitting diodes provided in a first specific embodiment of the second embodiment of the present disclosure.

FIG. 6 is a schematic diagram of a process of transferring massive light emitting diodes provided in a second specific embodiment of the second embodiment of the present disclosure.

FIG. 7 is a sub-flow chart of the method of transferring massive light emitting diodes provided in the first embodiment of the present disclosure.

FIG. 8 is a schematic diagram of a sub-process of transferring massive light emitting diodes provided in the first specific embodiment of the first embodiment of the present disclosure.

FIG. 9 is a schematic diagram of a sub-process of transferring massive light emitting diodes provided in the second specific embodiment of the first embodiment of the present disclosure.

FIGS. 10a and 10b are schematic diagrams of a display back plate assembly provided in embodiments of the present disclosure.

### DETAILED DESCRIPTION OF THE EMBODIMENTS

For a clearer and more precise understanding of the present disclosure, reference will now be made to the accompanying drawings. The drawings illustrate examples of embodiments of the disclosure, wherein like reference numerals refer to like elements. It is to be understood that the drawings are not to scale in the actual practice of the disclosure and are for illustrative purposes only and are not drawn to scale.

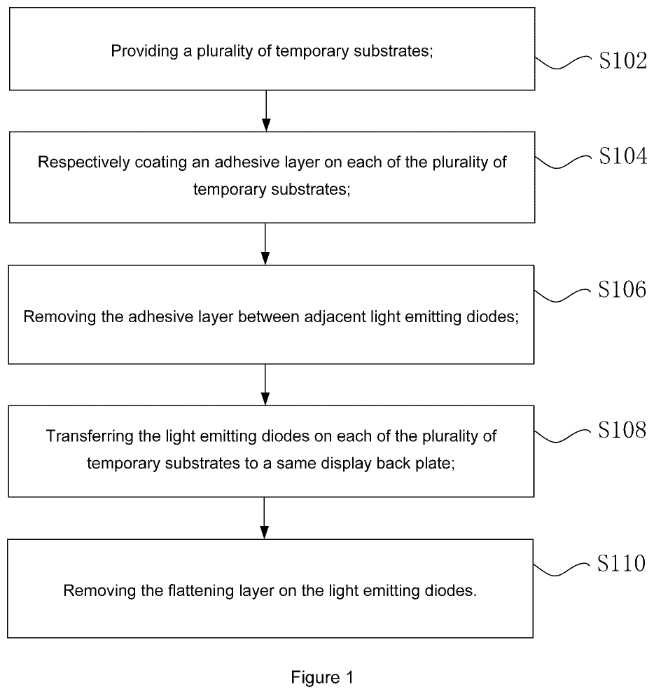

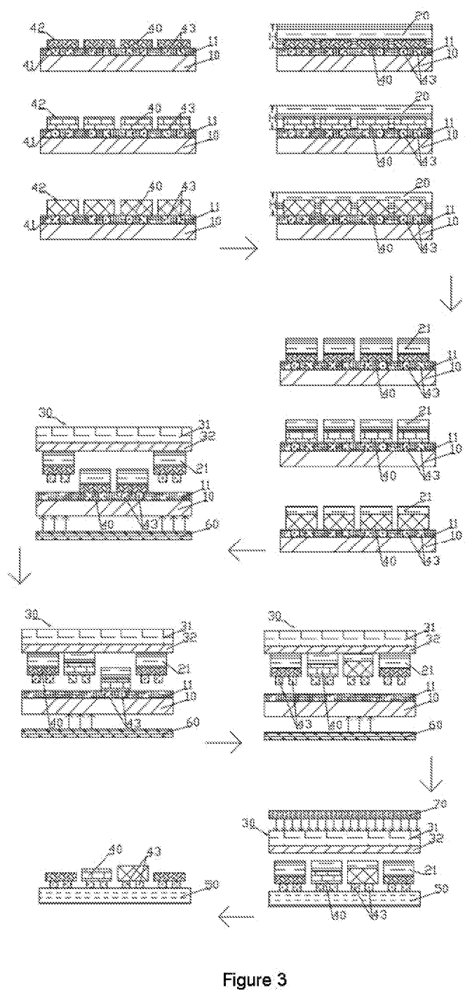

With reference to FIG. 1 and FIG. 3 in combination, FIG. 1 is a flow chart of a method for transferring massive light emitting diodes provided in a first embodiment of the present disclosure and FIG. 3 is a schematic diagram of a process of transferring massive light emitting diodes provided in a first specific embodiment of the first embodiment of the present disclosure. The method for transferring massive light emitting diodes specifically includes the following steps.

In step S102, a plurality of temporary substrates 10 are provided, and each of the plurality of temporary substrates 10 is provided with light emitting diodes 40 with one color. Specifically, a first end face 41, including an electrode 43, of the light emitting diode 40 faces the temporary substrate 10. The light emitting diodes 40 include a red micro light emitting diode, a blue micro light emitting diode, and a green micro light emitting diode, and the light emitting diodes 40 with different colors are different in height. The light emitting diode 40 is a micro light emitting diode in a flip-chip structure, and includes the first end face 41, a second end face 42 disposed opposite to the first end face 41, and two electrodes 43 included in the first end face 41. The temporary substrate 10 is coated with a first adhering layer 11, and the two electrodes 43 of the light emitting diode 40 are embedded in the first adhering layer 11 so that the first end face 41 is attached to the first adhering layer 11. A material of the first adhering layer 11 may be, but is not limited to, a photosensitive adhesive material or a pyrolytic adhesive.

In step S104, an adhesive layer 20 is respectively coated on each of the plurality of temporary substrates 10, so that the adhesive layer 20 covers the light emitting diodes 40 and the adhesive layer 20 on each of the plurality of temporary substrates 10 is the same in height H. A material of adhesive layer 20 may be, but is not limited to, photoresist.

In step S106, the adhesive layer 20 between adjacent light emitting diodes 40 is removed. Specifically, the adhesive layer 20 between adjacent light emitting diodes 40 is removed by exposure or etching to form a flattening layer 21 on one side, far away from the temporary substrate 10, of the light emitting diodes 40 with the different colors.

In step S108, the light emitting diodes 40 on each of the plurality of temporary substrates 10 are transferred to a same display back plate 50. Specifically, a transfer device 30 is provided, which includes a transfer substrate 31, a second adhering layer 32 is coated on the transfer substrate 31. A material of the second adhering layer 32 may be, but is not limited to, a photosensitive adhesive material or a pyrolytic adhesive. The light emitting diodes 40 on each of the plurality of temporary substrates 10 are respectively and selectively picked up by the transfer device 30, so that the light emitting diodes 40 with each color are alternately adhered to the transfer substrate 31 at intervals by the second adhering layer 32. The light emitting diodes 40 are transferred to the display back plate 50 using the transfer device 30. While the light emitting diodes 40 on each of the plurality of temporary substrates 10 are respectively and selectively picked up by the transfer device 30, a tackiness of the first adhering layer 11 is reduced by a tackiness reducing device 60 so that the tackiness of the first adhering layer 11 is less than that of the second adhering layer 32. Specifically, the tackiness reducing device 60 is placed on one side, far away from the light emitting diodes 40, of the temporary substrate 10. When the light emitting diodes 40 are selectively adhered by the transfer device 30, the tackiness reducing device 60 reduces the tackiness of the first adhering layer 11 at corresponding positions to which the light emitting diodes 40 are adhered. And when the material of the first adhering layer 11 is a photosensitive adhesive material, the tackiness reducing device 60 is an illumination device. Laser light, radial light or other light beams emitted by the illumination device can be irradiated to the first adhering layer 11 at the corresponding positions to which the light emitting diodes 40 are adhered through the temporary substrate 11, and the tackiness of the first adhering layer 11 is reduced. When the material of the first adhering layer 11 is a pyrolytic adhesive, the tackiness reducing device 60 is a heating device. The heating device reduces the tackiness of the first adhering layer 11 by heating the first adhering layer 11 at the corresponding positions to which the light emitting diodes 40 are adhered. While the light emitting diodes 40 are transferred to the display back plate 50 by the transfer device 30, the tackiness of the second adhering layer 32 is removed by a peeling device 70 to peel off the transfer device 30. Specifically, the peeling device 70 is placed on one side, far away from the light emitting diodes 40, of the transfer substrate 31. When the material of the second adhering layer 32 is a photosensitive adhesive material, the peeling device 70 is an illumination device. The laser light or other light beams emitted by the illumination device can be irradiated to the second adhering layer 32 through the transfer substrate 31 to remove the tackiness of the second adhering layer 32. When the material of the second adhering layer 32 is a pyrolytic adhesive, the peeling device 70 is a heating device. The tackiness of the second adhering layer 32 is removed by heating the second adhering layer 32 by the heating device.

In step S110, the flattening layer 21 on the light emitting diodes is removed. Specifically, the flattening layer 21 on the second end face 42 of the light emitting diode 40 is removed using a solvent or a photoresist removal solution.

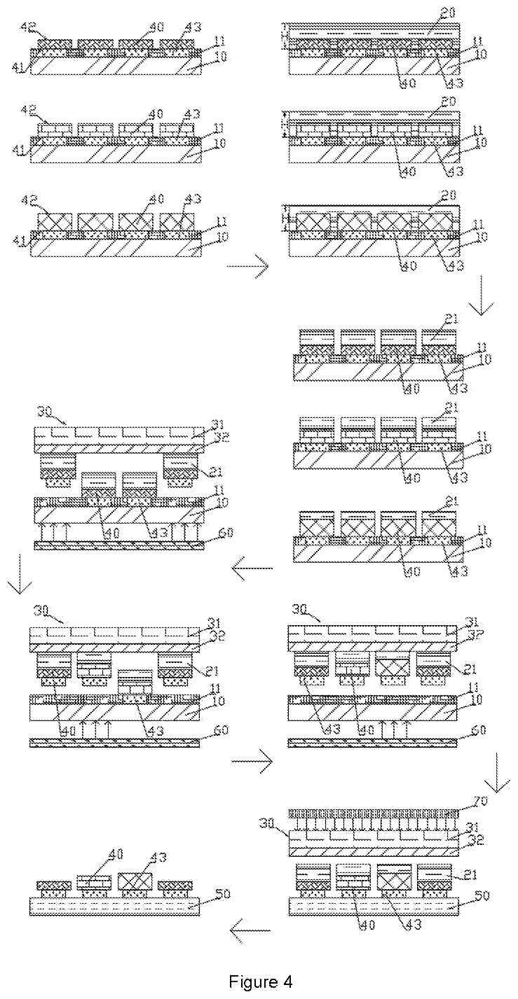

With reference to FIG. 1 and FIG. 4 in combination, FIG. 1 is the flow chart of a method for transferring massive light emitting diodes provided in a first embodiment of the present disclosure and FIG. 4 is a schematic diagram of a process of transferring massive light emitting diodes provided in a second specific embodiment of the first embodiment of the present disclosure. The method for transferring massive light emitting diodes provided in the second specific embodiment differs from the method for transferring massive light emitting diodes provided in the first specific embodiment in that the light emitting diode 40 is a micro light emitting diode of a vertical structure, and includes a first end face 41, a second end face 42 disposed opposite to the first end face 41, and one electrode 43 included in the first end face 41. The other steps of the method for transferring massive light emitting diodes provided in the second specific embodiment are substantially identical to those of the method for transferring massive light emitting diodes provided in the first specific embodiment and will not be described in detail herein.

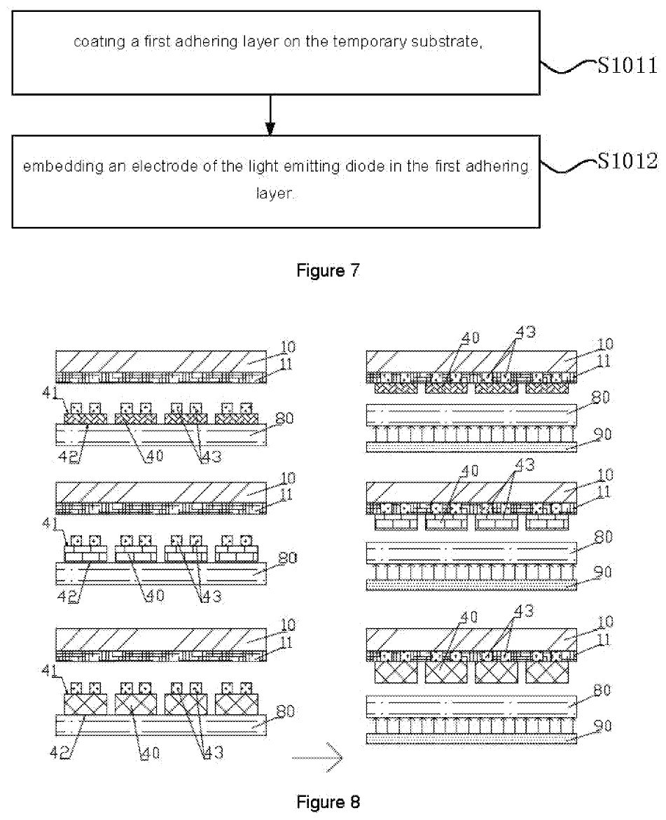

With reference to FIG. 7 and FIG. 8 in combination, FIG. 7 is provided a sub-flow chart of the method of transferring massive light emitting diodes provided in the first embodiment of the present disclosure and FIG. 8 is a schematic diagram of a sub-process of transferring massive light emitting diodes provided in the first specific embodiment of the first embodiment of the present disclosure. Before the execution of step S102 and the provision of a plurality of temporary substrates 10, the method for transferring massive light emitting diodes further includes the following steps.

In step S1011, the first adhering layer 11 is coated on the temporary substrate 10.

S1012, the electrode 43 of the light emitting diode 40 is embedded in the first adhering layer 11, so that the first end face 41 is attached to the first adhering layer 11. Specifically, the first adhering layer 11 coated on the temporary substrate 10 faces the light emitting diodes 40 formed on original substrate 80. And the light emitting diodes 40 with the same color are formed on the same original substrate 80. The temporary substrate 10 is moved in the direction of closing to the original substrate 80 so that the electrode 43 of the light emitting diode 40 is embedded in the first adhering layer 11, and the light emitting diodes 40 are adhered to the temporary substrate 10 through the first adhering layer 11. The original substrate 80 is peeled off by a laser device 90, and the laser device 90 is placed on one side, far away from the light emitting diodes 40, of the original substrate 80, so that the laser light emitted by the laser device 90 is irradiated to the light emitting diodes 40 through the original substrate 80, thereby peeling off the original substrate 80.

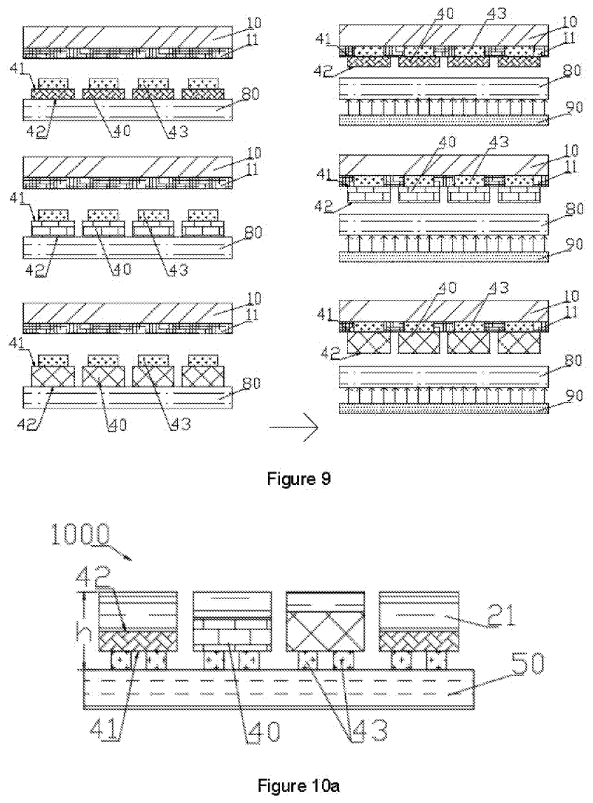

With reference to FIG. 7 and FIG. 9 in combination, FIG. 7 is provided the sub-flow chart of a method for transferring massive light emitting diodes provided in the first embodiment of the present disclosure and FIG. 9 is a schematic diagram of a sub-process of transferring massive light emitting diodes provided in the second specific embodiment of the first embodiment of the present disclosure. The sub-method for transferring massive light emitting diodes provided in the second specific embodiment differs from the sub-method for transferring massive light emitting diodes provided in the first specific embodiment in that the light emitting diode 40 is a micro light emitting diode of a vertical structure, and includes a first end face 41, a second end face 42 disposed opposite the first end face 41, and one electrode 43 included in the first end face 41. The other steps of the sub-method for transferring massive light emitting diodes provided in the second specific embodiment are substantially identical to those of the sub-method for transferring massive light emitting diodes provided in the first specific embodiment and will not be described in detail herein.

In the above-described embodiment, the adhesive layer 20 is respectively coated on each temporary substrate 10 such that the flattening layer 21 is formed on one side, far away from the temporary substrate 10, of the light emitting diodes 40 with the different colors, and a height of one side, far away from the temporary substrate 10, of the flattening layer 21 to the temporary substrate 10 is the same. The light emitting diodes 40 with the different colors are respectively and selectively picked up by the transfer devices 30, so that the light emitting diodes 40 with the different colors are alternately adhered to the transfer devices 30 at intervals, thereby transferring the light emitting diodes 40 with different heights and the different colors to the display back plate 50 at one time.

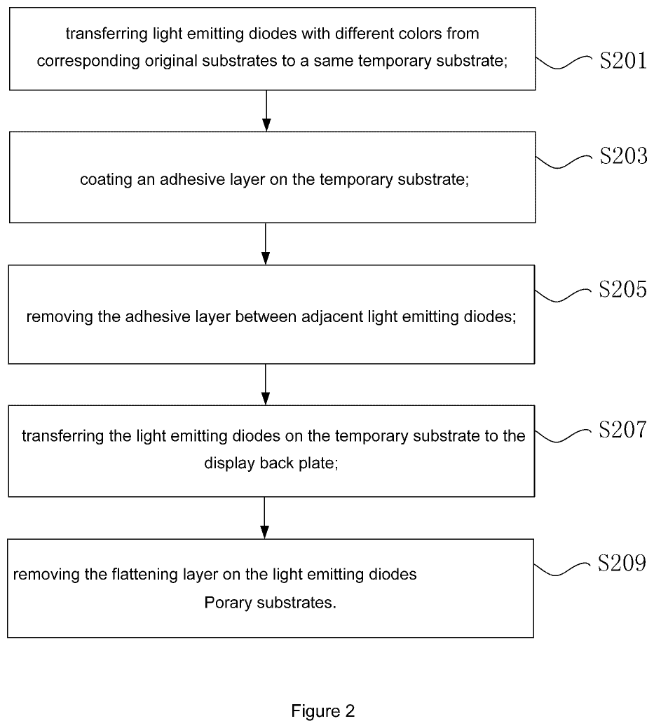

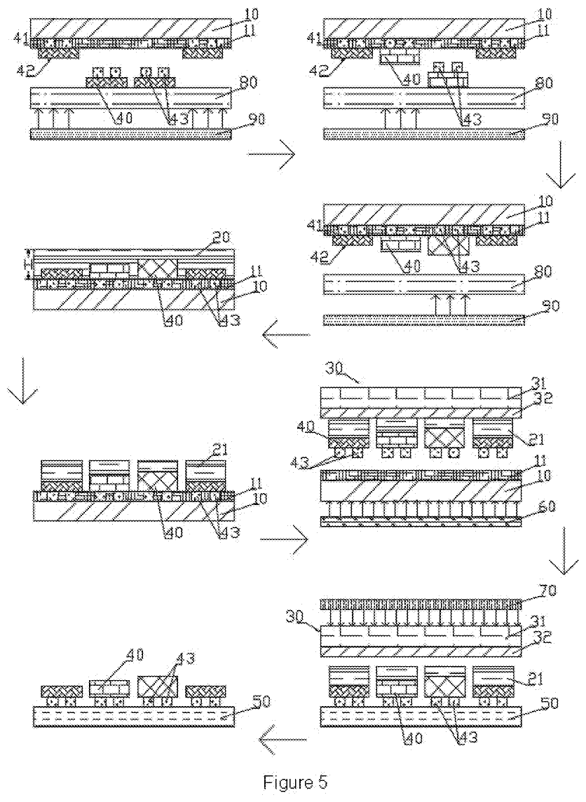

With reference to FIG. 2 and FIG. 5 in combination, FIG. 2 is a flow chart of a method for transferring massive light emitting diodes provided in a second embodiment of the present disclosure and FIG. 5 is a schematic diagram of a process of transferring massive light emitting diodes provided in a first specific embodiment of the second embodiment of the present disclosure. The method for transferring massive light emitting diodes specifically includes the following steps.

In step S201, light emitting diodes 40 with different colors are transferred from the corresponding original substrate 80 to the same temporary substrate 10. The light emitting diodes 40 include a red micro light emitting diode, a blue micro light emitting diode, and a green micro light emitting diode, and the light emitting diodes 40 with the different colors are different in height. The light emitting diode 40 is a micro light emitting diode of a flip-chip structure, and includes a first end face 41, a second end face 42 disposed opposite to the first end face 41, and two electrodes 43 included in the first end face 41. Specifically, the first adhering layer 11 is coated on the temporary substrate 10, wherein the material of the first adhering layer 11 may be, but is not limited to, a photosensitive adhesive material or a pyrolytic adhesive. The first adhering layer 11 faces the light emitting diodes 40 formed on the original substrate 80. And the light emitting diodes 40 with the same color are formed on the same original substrate 80. The temporary substrate 10 is moved in the direction of closing to the original substrate 80, the light emitting diodes 40 on each original substrate 80 are respectively and selectively transferred using the temporary substrate 10 according to a sequence that heights of the light emitting diodes 40 are from low to high, and the electrodes 43 of the light emitting diodes 40 to be transferred are embedded into the first adhering layer 11, so that the first end face 41 is attached to the first adhering layer 11, and the light emitting diodes 40 with the different colors are alternately adhered to the temporary substrate 10 at intervals through the first adhering layer 11. The first end face 41, including the electrodes 43, of the light emitting diode 40 faces the temporary substrate 10. When the light emitting diodes 40 are selectively transferred by the temporary substrate 10, the light emitting diodes 40 to be transferred are peeled off by the laser device 90, and the laser device 90 is placed on one side, far away from the light emitting diodes 40, of the original substrate 80, so that the laser light emitted by the laser device 90 is irradiated to the light emitting diodes 40 to be transferred through the original substrate 80, thereby peeling off the light emitting diodes 40 to be transferred.

In step S203, the adhesive layer 20 is coated on the temporary substrate 10 so that the adhesive layer 20 covers the light emitting diode 40s and the adhesive layer 20 is the same in height H. A material of adhesive layer 20 may be, but is not limited to, photoresist.

In step S205, the adhesive layer 20 between adjacent light emitting diodes 40 is removed. Specifically, the adhesive layer 20 between adjacent light emitting diodes 40 is removed by exposure or etching to form the flattening layer 21 on one side, far away from the temporary substrate 10, of the light emitting diodes 40 with the different colors.

In step S207, the light emitting diodes 40 on the temporary substrate 10 are transferred to a display back plate 50. Specifically, a transfer device 30 is provided, which includes a transfer substrate 31, and a second adhering layer 32 is coated on the transfer substrate 31. The material of the second adhering layer 32 may be, but is not limited to, a photosensitive adhesive material or a pyrolytic adhesive. The light emitting diodes 40 on the temporary substrate 10 are picked up by the transfer device 30, adhered to the transfer substrate 31 by the second adhering layer 32, and transferred to the display back plate 50 by the transfer device 30. While the light emitting diodes 40 on the temporary substrate 10 are picked up by the transfer device 30, a tackiness of the first adhering layer 11 is reduced by a tackiness reducing device 60 so that the tackiness of the first adhering layer 11 is less than that of the second adhering layer 32. Specifically, the tackiness reducing device 60 is placed on one side, far away from the light emitting diodes 40, of the temporary substrate 10. When the transfer device 30 is attached to the light emitting diode 40, the tackiness reducing device 60 reduces the tackiness of the first adhering layer 11. When the material of the first adhering layer 11 is a photosensitive adhesive material, the tackiness reducing device 60 is an illumination device. The laser light or other light beams emitted by the illumination device can be irradiated to the first adhering layer 11 through the temporary substrate 11 to reduce the tackiness of the first adhering layer 11. When the material of the first adhering layer 11 is a pyrolytic adhesive, the tackiness reducing device 60 is a heating device. The tackiness of the first adhering layer 11 is reduced by heating the first adhering layer 11 by the heating device. While the light emitting diodes 40 are transferred to the display back plate 50 by the transfer device 30, the tackiness of the second adhering layer 32 is removed by the peeling device 70 to peel off the transfer device 30. Specifically, the peeling device 70 is placed on one side far away from the light emitting diodes 40, of the transfer substrate 31. When the material of the second adhering layer 32 is a photosensitive adhesive material, the peeling device 70 is an illumination device. Laser light, redial light or other light beams emitted by the illumination device can be irradiated to the second adhering layer 32 through the transfer substrate 31 to remove the tackiness of the second adhering layer 32. When the material of the second adhering layer 32 is a pyrolytic adhesive, the peeling device 70 is a heating device. The tackiness of the second adhering layer 32 is removed by heating the second adhering layer 32 by the heating device.

In step S209, the flattening layer 21 on the light emitting diodes 40 is removed. Specifically, the flattening layer 21 on the second end face 42 of the light emitting diode 40 is removed using a solvent or a photoresist removal solution.

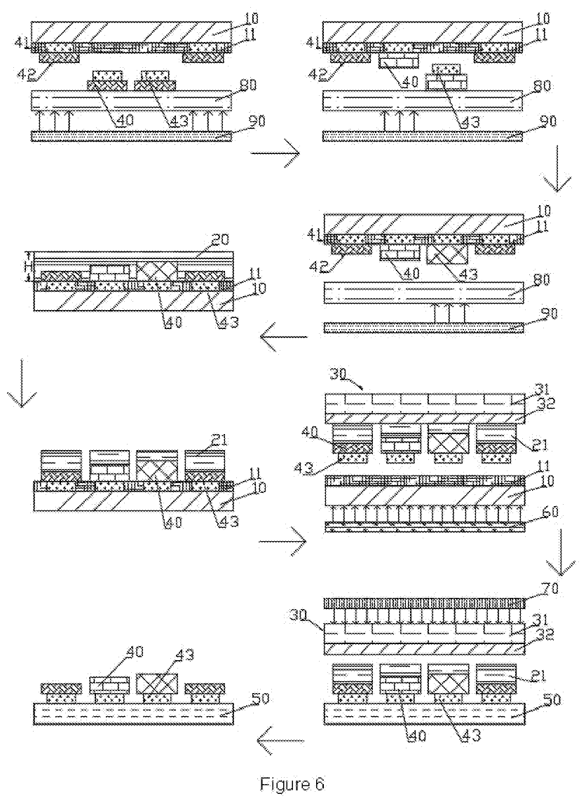

With reference to FIG. 2 and FIG. 6 in combination, FIG. 2 is the flow chart of a method for transferring massive light emitting diodes provided in the second embodiment of the present disclosure and FIG. 6 is a schematic diagram of a process of transferring massive light emitting diodes provided in a second specific embodiment of the second embodiment of the present disclosure. The method for transferring massive light emitting diodes provided in the second specific embodiment differs from the method for transferring massive light emitting diodes provided in the first specific embodiment in that the light emitting diode 40 is a micro light emitting diode of a vertical structure, and includes a first end face 41, a second end face 42 disposed opposite to the first end face 41, and one electrode 43 included in the first end face 41. The other steps of the method for transferring massive light emitting diodes provided in the second specific embodiment are substantially identical to those of the method for transferring massive light emitting diodes provided in the first specific embodiment and will not be described in detail herein.

In the above embodiments, the light emitting diodes 40 formed on different original substrates 80 are first transferred to the same temporary substrate 10 so that the light emitting diodes 40 with the different colors are alternately attached to the temporary substrate 10 at intervals. An adhesive layer 20 is coated on the temporary substrate 10, so that a flattening layer 21 is formed on one side, far away from the temporary substrate 10, of the light emitting diodes 40 with the different colors, and a height from one side, far away from the temporary substrate 10, of the flattening layer 21 to the temporary substrate 10 is the same. The light emitting diodes 40 are picked up by the transfer device 30, so that the light emitting diodes 40 with different heights and the different colors can be transferred to the display back plate 50 at one time.

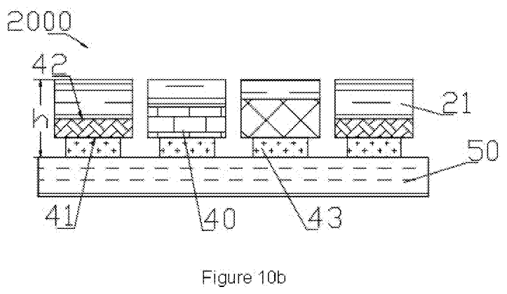

With reference to FIG. 10a, a schematic diagram of a display back plate assembly 1000 is provided in accordance with an embodiment of the present disclosure. The display back plate assembly 1000 includes a display back plate 50, light emitting diodes 40, and a flattening layer 21. Specifically, light emitting diodes 40 with different colors are disposed on the display back plate 50. The light emitting diodes 40 include a red micro light emitting diode, a blue micro light emitting diode and a green micro light emitting diode, the light emitting diodes 40 with the different colors are alternately arranged on the display back plate 50 at intervals, and the light emitting diodes 40 with the different colors are different in height. The light emitting diode 40 is a micro light emitting diode of a flip-chip structure, and includes a first end face 41, a second end face 42 disposed opposite to the first end face 41, and two electrodes 43 included in the first end face 41. The first end face 41 including two electrodes 43 faces the display back plate 50.

The flattening layer 21 is formed on the one side, far away from the display back plate 50, of the light emitting diodes 40 with the different colors, distances are the same and are h, and the distance is from one side, far away from the display back plate 50, of a part of the flattening layer 21 corresponding to each light emitting diode 40 to the display back plate 50. A material of the flattening layer 21 is a photoresist.

With reference to FIG. 10b, a schematic diagram of a display back plate assembly 2000 is provided in accordance with an embodiment of the present disclosure. The display back plate assembly 2000 differs from the display back plate assembly 1000 in that the light emitting diode 40 is a micro light emitting diode of a vertical structure, and includes a first end face 41, a second end face 42 disposed opposite to the first end face 41, and one electrode 43 included in the first end face 41. Other structures of the display back plate assembly 2000 are substantially identical to those of the display back plate assembly 1000 and will not be described in detail herein.

It will be apparent to those skilled in the art that various modifications and variations can be made to the present disclosure without departing from the spirit or scope of the disclosure. Thus, it is intended that the present disclosure covers the modifications and variations of this disclosure provided they come within the scope of the appended claims and their equivalents.

The above-listed are only preferred embodiments of the present disclosure, which of course cannot be used to limit the scope of rights of the present disclosure. Therefore, equivalent changes made according to the claims of the present disclosure still fall within the scope of the present disclosure.

What is claimed is:

1. A method for transferring massive light emitting diodes, comprising:
providing a plurality of temporary substrates, wherein light emitting diodes with one color are arranged on one of the plurality of temporary substrates, and the light emitting diodes with different colors are different in height;
respectively coating an adhesive layer on each of the plurality of temporary substrates, so that the adhesive layer covers the light emitting diodes and the adhesive layer on each of the plurality of temporary substrates is the same in height;
removing the adhesive layer between adjacent light emitting diodes to form a flattening layer on one side, far away from the temporary substrate, of the light emitting diodes with the different colors; and
transferring the light emitting diodes on each of the plurality of temporary substrates to a same display back plate.

2. The method according to claim 1, wherein the light emitting diodes with one color being arranged on one of the plurality of temporary substrates comprises:
a first end face, including an electrode, of the light emitting diode facing the temporary substrate, wherein the light emitting diodes include a red micro light emitting diode, a blue micro light emitting diode, and a green micro light emitting diode.

3. The method according to claim 2, before providing a plurality of temporary substrates, the further comprising:
coating a first adhering layer on the plurality of temporary substrates; and
embedding the electrodes of the light emitting diodes in the first adhering layer, so that the first end face is attached to the first adhering layer.

4. The method according to claim 1, wherein transferring the light emitting diodes on each of the plurality of temporary substrates to the same display back plate specifically comprises:
providing a transfer device, coating a second adhering layer on a transfer substrate of the transfer device, respectively and selectively picking up the light emitting diodes on each of the plurality of temporary substrates by the transfer device, so that the light emitting diodes with each color are alternately adhered to the transfer substrate at intervals through the second adhering layer, and transferring the light emitting diodes to the display back plate by the transfer device.

5. The method according to claim 4, wherein respectively and selectively picking up the light emitting diodes on each of the plurality of temporary substrates by the transfer device specifically comprises:
reducing a tackiness of the first adhering layer using a tackiness reducing device so that the tackiness of the first adhering layer is less than a tackiness of the second adhering layer.

6. The method according to claim 1, after transferring the light emitting diodes on each of the plurality of temporary substrates to the same display back plate, the method further comprising:
removing the flattening layer on the light emitting diodes.

7. A method for transferring massive light emitting diodes, comprising:
attaching light emitting diodes with different colors from corresponding original substrates to a same temporary substrate, wherein the light emitting diodes with the different colors are different in height;
coating an adhesive layer on the temporary substrate, so that the adhesive layer covers the light emitting diodes and the adhesive layer is the same in height;
removing the adhesive layer between adjacent light emitting diodes to form a flattening layer on one side, far away from the temporary substrate, of the light emitting diodes with the different colors; and
transferring the light emitting diodes on the temporary substrate to a display back plate.

8. The method according to claim 7, wherein attaching the light emitting diodes with the different colors from the corresponding original substrates to the same temporary substrate specifically comprises:
a first end face, including an electrode, of the light emitting diode facing the temporary substrate, wherein the light emitting diodes with the different colors include a red micro light emitting diode, a blue micro light emitting diode, and a green micro light emitting diode.

9. The method according to claim 8, wherein attaching the light emitting diodes with the different colors from the corresponding original substrates to the same temporary substrate further comprises:
coating a first adhering layer on the temporary substrate, respectively and selectively attaching the light emitting diodes on each original substrate using the temporary substrate according to a sequence that heights of the light emitting diodes are from low to high, and embedding the electrodes of the light emitting diodes in the first adhering layer so that the first end face is adhered to the first adhering layer and the light emitting diodes with the different colors are alternately adhered to the temporary substrate at intervals through the first adhering layer.

10. The method according to claim 7, wherein transferring the light emitting diodes on the temporary substrate to the display back plate specifically comprises:
providing a transfer device, coating a second adhering layer on a transfer substrate of the transfer device, picking up the light emitting diodes on the temporary substrate by the transfer device, adhering the light emitting diodes to the transfer substrate through the second adhering layer, and transferring the light emitting diodes to the display back plate by the transfer device.

11. The method according to claim 10, wherein picking up the light emitting diodes on the temporary substrate by the transfer device specifically comprises:
reducing a tackiness of the first adhering layer using a tackiness reducing device so that the tackiness of the first adhering layer is less than a tackiness of the second adhering layer.

12. The method according to claim 7, after transferring the light emitting diodes on the temporary substrate to the display back plate, the method further comprising:
removing the flattening layer on the light emitting diodes.

13. A display back plate assembly, comprising:
a display back plate;
light emitting diodes with different colors arranged on the display back plate, wherein the light emitting diodes with the different colors are different in height; and
a flattening layer formed on one side, far away from the display back plate, of the light emitting diodes with the different colors, wherein distances are the same, and the distance is from one side, far away from the display back plate, of a part of the flattening layer corresponding to each light emitting diode to the display back plate.

14. The display back plate assembly according to claim 13, wherein the light emitting diodes include a red micro light emitting diode, a blue micro light emitting diode, and a green micro light emitting diode, the light emitting diodes with the different colors being alternately arranged on the display back plate at intervals.

15. The display back plate assembly according to claim 13, wherein a first end face, including an electrode, of the light emitting diode faces the display back plate.

16. The display back plate assembly according to claim 13, wherein a material of the flattening layer is photoresist.
